(19) United States
(12) Patent Application Publication
(10) Pub. No.: US 2025/0290198 A1
(43) Pub. Date: Sep. 18, 2025

(54) METHOD OF DEPOSITING SILICON NITRIDE THIN FILM IN TRENCH OF SUBSTRATE

(71) Applicant: ASM IP Holding B.V., Almere (NL)

(72) Inventors: Annisa Noorhidayati, Tokyo (JP); Musa Alaydrus, Helsinki (FI); Agung Setiadi, Tokyo (JP)

(21) Appl. No.: 19/075,175

(22) Filed: Mar. 10, 2025

Related U.S. Application Data
(60) Provisional application No. 63/564,636, filed on Mar. 13, 2024.

(51) Int. Cl. C23C 16/04; C23C 16/34; C23C 16/455; C23C 16/458

(52) U.S. Cl. CPC C23C 16/045; C23C 16/345; C23C 16/45536; C23C 16/45553; C23C 16/458

(57) ABSTRACT

A method of depositing a silicon nitride thin film is provided. The method may comprise steps of: (a) placing a substrate on a susceptor in a reaction chamber; wherein the substrate comprises a trench; (b) introducing a silicon precursor into the reaction space; (c) exposing the substrate to a nitrogen-containing gas to purge excess silicon precursor and byproducts; (d) introducing the silicon precursor into the reaction space; (e) exposing the substrate to the nitrogen-containing gas to purge excess silicon precursor and byproducts; (f) exposing the substrate to reactive species generated by a plasma from the nitrogen-containing gas; and (g) exposing the substrate to the nitrogen-containing gas to purge excess reactive species and byproducts.

### CROSS-REFERENCE TO RELATED APPLICATIONS

This application claims priority to U.S. Provisional Patent Application Ser. No. 63/564,636 filed Mar. 13, 2024 titled METHOD OF DEPOSITING SILICON NITRIDE THIN FILM IN TRENCH OF SUBSTRATE, the disclosure of which is hereby incorporated by reference in its entirety.

### FIELD OF INVENTION

The present disclosure generally relates to methods for forming a silicon nitride film. More particularly, examples of the disclosure relate to methods for forming a silicon nitride thin film in a trench within a substrate.

### BACKGROUND OF THE DISCLOSURE

In manufacturing processes of large-scale integrated circuits (LSIs), there are several processes for forming sidewalls in trenches. The sidewalls are used as spacers or used for blocking etching of a structure from side surfaces of trenches. The sidewalls may be formed by depositing a conformal film on surfaces of trenches.

A silicon nitride (SiN) film may be used as the sidewalls. One approach for forming a SiN film is a plasma enhanced atomic layer deposition (PEALD) process. The SiN may be formed by providing a silicon-containing precursor and generating a plasma using N2. An exemplary method is disclosed in U.S. Pat. No. 10,424,477, which is hereby incorporated by reference.

There is a need to improve a conformality of a SiN film in a trench of a substrate.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of forming a silicon nitride thin film is provided. The method may comprise steps of: (a) placing a substrate on a susceptor in a reaction chamber; wherein the substrate comprises a trench; (b) introducing a silicon precursor into the reaction space; (c) exposing the substrate to a nitrogen-containing gas to purge excess silicon precursor and byproducts; (d) introducing the silicon precursor into the reaction space; (e) exposing the substrate to the nitrogen-containing gas to purge excess silicon precursor and byproducts; (f) exposing the substrate to reactive species generated by a plasma from the nitrogen-containing gas; and (g) exposing the substrate to the nitrogen-containing gas to purge excess reactive species and byproducts.

In accordance with further exemplary embodiments of the disclosure, the nitrogen-containing gas may be provided continuously.

In accordance with further exemplary embodiments of the disclosure, the method may further comprise step (h) introducing a hydrogen-containing gas during step (b).

In accordance with further exemplary embodiments of the disclosure, the method may further comprise step (i) introducing a hydrogen-containing gas from before step (b) to the end of step (c).

In accordance with further exemplary embodiments of the disclosure, steps (i), (b) and (c) may be repeated N times and steps (d) to (g) may be repeated M times.

In accordance with further exemplary embodiments of the disclosure, the silicon precursor may comprise at least one of: HSiI3, H2SiI2, H3SiI, H2Si2I4, H4Si2I2, H5Si2I, H2SiCl2, or H2SiBr2.

In accordance with further exemplary embodiments of the disclosure, the method may be performed at a temperature between 275° C. and 550° C.

In accordance with further exemplary embodiments of the disclosure, the method may be performed at a pressure between 2 Torr and 22.5 Torr.

In accordance with further exemplary embodiments of the disclosure, a RF power of the plasma may be between 100 W and 2000 W.

In accordance with further exemplary embodiments of the disclosure, the silicon nitride thin film may exhibit more than 90% conformality.

In accordance with further exemplary embodiments of the disclosure, the conformality may be the ratio of the thickness of the sidewall at a point 110 nm from the top in the direction of trench depth to the film thickness at the top of the trench, multiplied by 100.

In accordance with further exemplary embodiments of the disclosure, a duration of the step (b) may be between 0.3 and 3 seconds.

In accordance with further exemplary embodiments of the disclosure, a duration of the step (c) may be between 0.1 and about 1.5 seconds.

In accordance with further exemplary embodiments of the disclosure, a duration of the step (d) may be between 0.3 and about 3 seconds.

In accordance with further exemplary embodiments of the disclosure, a duration of the step (e) may be between 0.1 and about 1.5 seconds.

In accordance with further exemplary embodiments of the disclosure, a duration of the step (f) may be between 3 and about 30 seconds.

In accordance with further exemplary embodiments of the disclosure, a duration of the step (g) may be between 0.1 and about 2 seconds.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a schematic image of structures in accordance with exemplary embodiments of the disclosure.

FIG. 3 illustrates a timing sequence in accordance with exemplary embodiments of the disclosure.

FIG. 4 illustrates another timing sequence in accordance with exemplary embodiments of the disclosure.

FIG. 5 illustrates another timing sequence in accordance with exemplary embodiments of the disclosure.

FIG. 6 illustrates a timing sequence in a prior art.

FIG. 7 illustrate a schematic image of step 402 in the FIG. 6.

FIG. 8 illustrate a schematic image of steps 301 and 302 in the FIG. 5.

FIG. 9 illustrates scanning transmission electron microscopy images of structures in accordance with exemplary embodiments of the disclosure.

FIG. 10 illustrates other scanning transmission electron microscopy images of structures in accordance with exemplary embodiments of the disclosure.

FIG. 11 illustrates a plasma reactor system in accordance with exemplary embodiments of the disclosure is illustrated.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

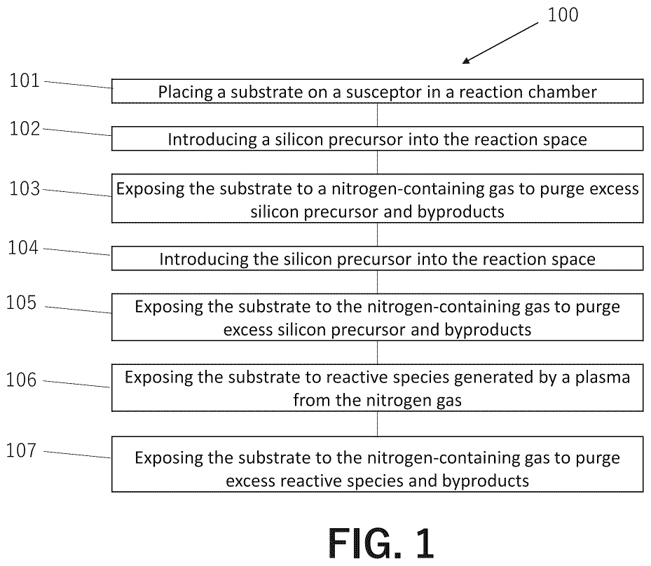

FIG. 1 illustrates a method 100 in accordance with exemplary embodiments of the disclosure. The method 100 may include: (a) placing a substrate on a susceptor in a reaction chamber (step 101); (b) introducing a silicon precursor into the reaction space (step 102); (c) exposing the substrate to a nitrogen-containing gas (e.g. N2) to purge excess silicon precursor and byproducts (step 103); (d) introducing the silicon precursor into the reaction space (step 104); (e) exposing the substrate to the nitrogen-containing gas to purge excess silicon precursor and byproducts (step 105); (f) exposing the substrate to reactive species generated by a plasma from the nitrogen-containing gas (step 106); and (g) exposing the substrate to the nitrogen-containing gas to purge excess reactive species and byproducts (step 107). According to the method 100, a thin film comprising silicon nitride of a desired thickness may be formed in the trench.

As shown in FIG. 1, during the step 101, a substrate is provided into a reaction chamber of a gas-phase reactor. In accordance with examples of the disclosure, the reaction chamber can form part of a plasma-enhanced atomic layer deposition (PEALD) reactor.

During the step 101, the substrate may be brought to a desired temperature and the reaction chamber can be brought to a desired pressure, such as a temperature and pressure suitable for subsequent steps. By way of examples, a temperature (e.g., of a substrate or a substrate support) within a reaction chamber may range between 275° C. and 550° C. By way of examples, a pressure within the reaction chamber may range between 2 Torr and 22.5 Torr. The substrate may include one or more features, such as trenches.

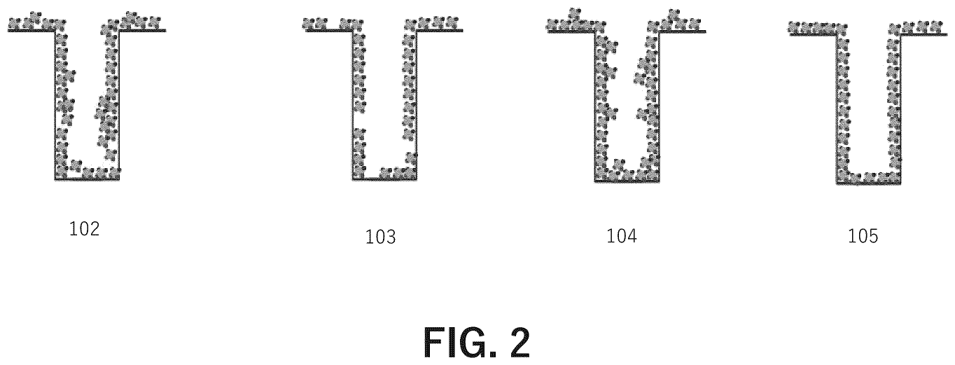

FIG. 2 illustrates a schematic image of structures in accordance with exemplary embodiments of the disclosure. During the step 102, the precursor for forming the film may be introduced into the reaction chamber. Exemplary precursor may include at least one of: HSiI3, H2SiI2, H3SiI, H2Si2I4, H4Si2I2, H5Si2I, H2SiCl2, or H2SiBr2.

During the step 103 (cut-off purge step), a nitrogen-containing gas may be provided to the reaction chamber, thereby purging excess silicon precursor and byproducts. This step can reduce the physisorption, expose the unoccupied chemisorption sites, and increase chemisorption probability, resulting in a more neatly and densely arranged film.

Again, the silicon precursor may be introduced into the reaction chamber during the step 104 and the nitrogen-containing gas may be provided to the reaction chamber during the step 105, thereby purging excess silicon precursor and byproducts.

During the step 106, the plasma may be generated using a direct plasma system by a radio frequency (RF) plasma source including a high frequency (HF) component and/or a low frequency (LF) component 108. By providing the plasma, the precursor reacts with the reactant to form a film. The high frequency (HF) may have a frequency in a range between about 13 MHz and about 27 MHz and the low frequency (LF) power may have a frequency in a range between about 100 KHz and about 500 KHz. The high frequency RF power may be between 100 watts and 2000 watts.

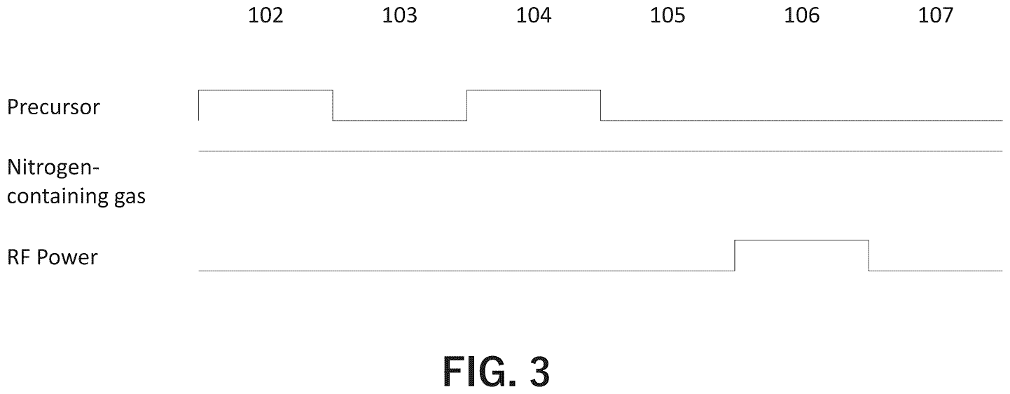

FIG. 3 illustrates a timing sequence in accordance with exemplary embodiments of the disclosure. The nitrogen-containing gas may be provided continuously. A duration of the step 102 may be between 0.3 and 3 seconds. A duration of the step 103 may be between about 0.1 and about 1.5 seconds. A duration of the step 104 may be between 0.3 and 3 seconds. A duration of the step 105 may be between about 0.1 and about 1.5 seconds. A duration of the step 106 may be between 3 and about 30 seconds. A duration of the step 107 may be between about 0.1 and about 2 seconds.

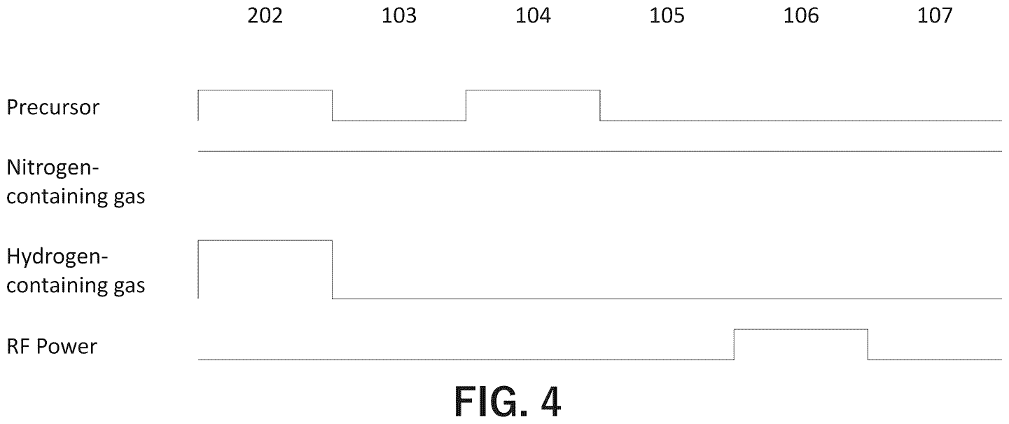

FIG. 4 illustrates another timing sequence in accordance with exemplary embodiments of the disclosure. The difference between this timing sequence and timing sequence in FIG. 3 is whether a hydrogen-containing gas (e.g. H2) is introduced at the same time as the precursor (step 202). By adding the step 103 after the step 202, it may give more freedom to introduce the hydrogen-containing gas as co-reactant, resulting in increasing GPC (Growth Per Cycle).

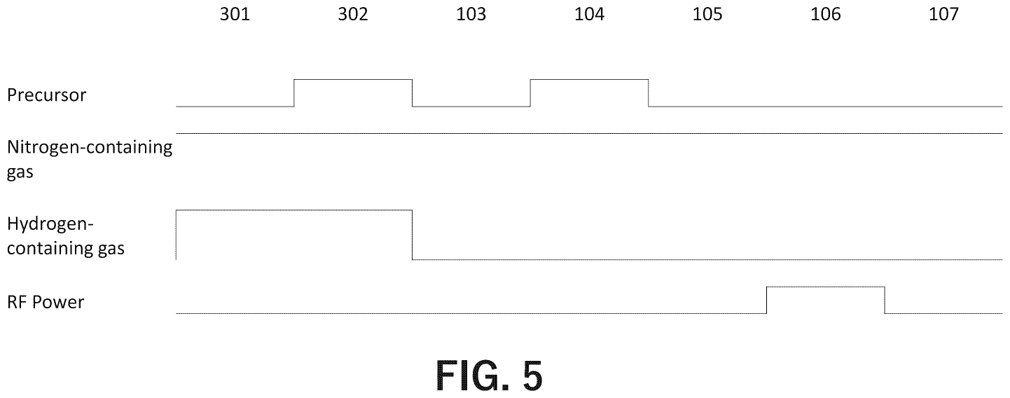

FIG. 5 illustrates another timing sequence in accordance with exemplary embodiments of the disclosure. The difference between this timing sequence and timing sequence in FIG. 4 is whether a hydrogen-containing gas is introduced before the precursor is provided (step 301). By introducing the hydrogen-containing gas before the precursor, it may promote more active chemisorption sites. Steps 301, 302, and 103 may be repeated N times and steps 104 to 107 may be repeated M times.

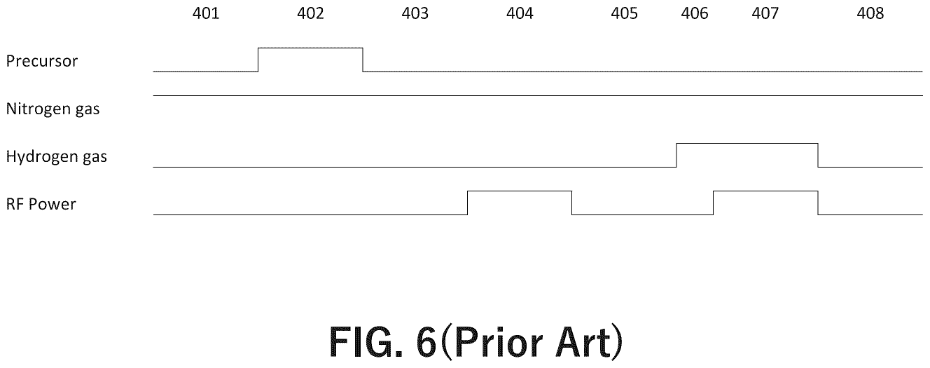

FIG. 6 illustrates a timing sequence in a prior art. This sequence comprises: introducing a silicon precursor into a reaction space (step 402); exposing a substrate to a nitrogen-containing gas to purge excess silicon precursor and byproducts (step 403); exposing the substrate to reactive species generated by a plasma from the nitrogen-containing gas (step 404); exposing the substrate to the nitrogen-containing gas to purge excess reactive species and byproducts (step 405); introducing a hydrogen-containing gas to the reaction space (step 406); exposing the substrate to reactive species generated by a plasma from the hydrogen-containing gas and nitrogen-containing gas (step 407); and exposing the substrate to the nitrogen-containing gas to purge excess reactive species and byproducts (step 408).

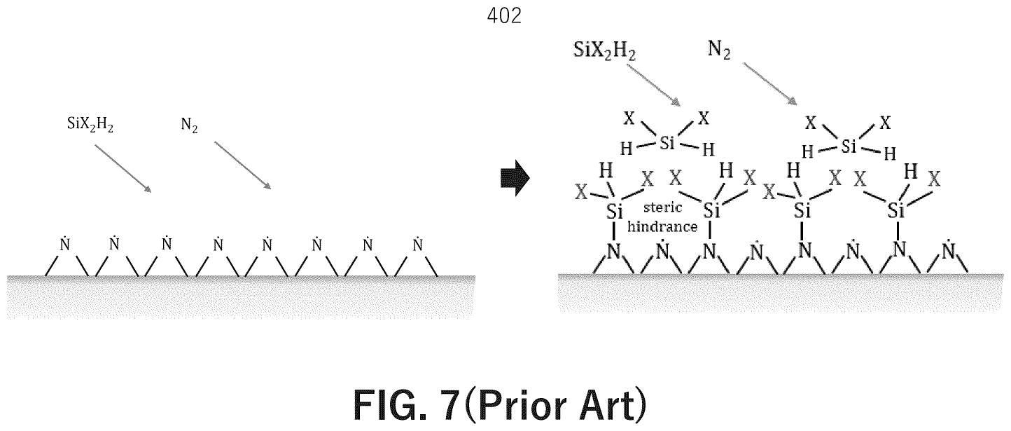

FIG. 7 illustrate a schematic image of step 402 in the FIG. 6. The precursor may be SiX2H2. X may be, for example, Iodine, chlorine, or bromine. As shown in FIG. 7, a steric hindrance may be caused between Xs, which may obstruct a chemisorption of other SiX2H2 molecules.

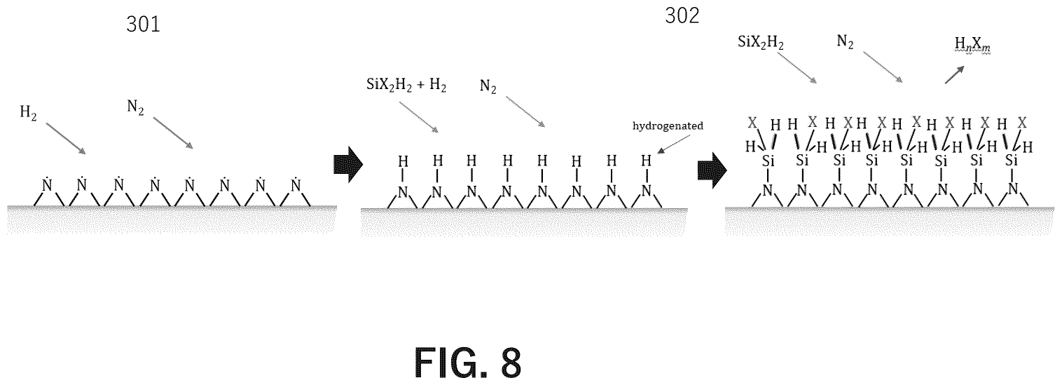

FIG. 8 illustrate a schematic image of steps 301 and 302 in the FIG. 5. During the step 301, a hydrogen-containing gas is introduced before SiX2H2 is provided. By introducing the hydrogen-containing gas, it may promote more active chemisorption sites. Therefore, SiX2H2 may be uniformly chemisorbed during step 302.

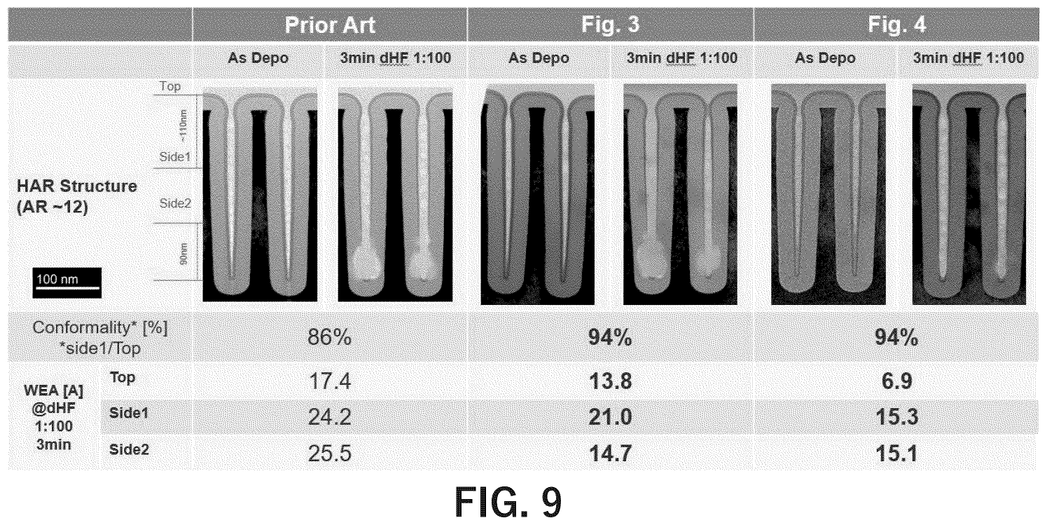

FIG. 9 illustrates scanning transmission electron microscopy images of structures in accordance with exemplary embodiments of the disclosure. As described, each of the timing sequences in FIG. 3 and FIG. 4 includes a step of exposing a substrate to a nitrogen-containing gas between silicon precursor feed steps. By adding this step, conformality and film quality on a three-dimensional structure can be improved.

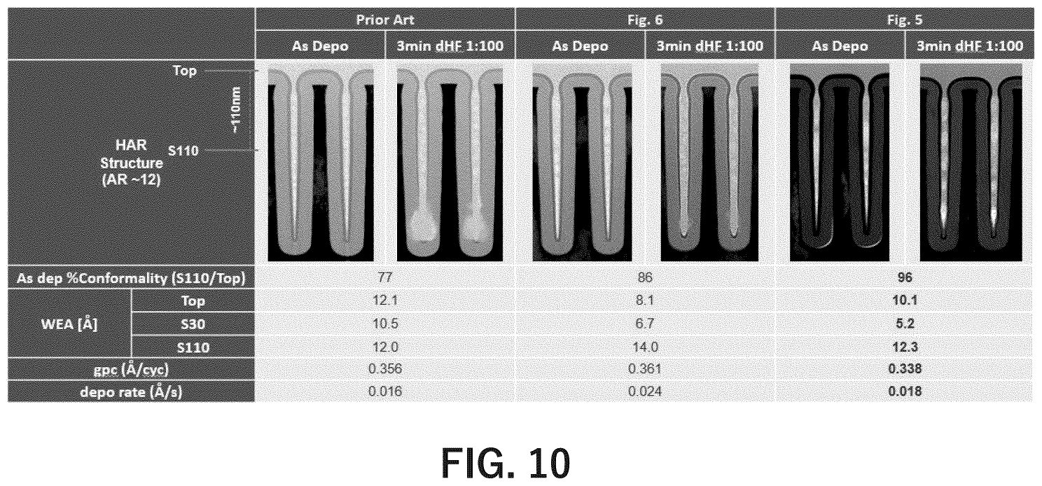

FIG. 10 illustrates other scanning transmission electron microscopy images of structures in accordance with exemplary embodiments of the disclosure. As described, the timing sequences in FIG. 5 includes a step of introducing a hydrogen-containing gas before the precursor. By adding this step, conformality and film quality on a three-dimensional structure can be further improved.

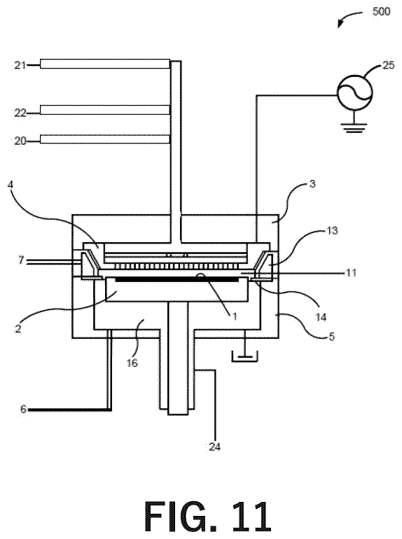

FIG. 11 illustrates a plasma reactor system 500 in accordance with exemplary embodiments of the disclosure is illustrated. The plasma reactor system 500 can be used to perform one or more steps or sub steps as described herein and/or to form one or more structures or portions thereof as described herein.

The plasma reactor system 500 may include a pair of electrically conductive flat-plate electrodes 4, 2 in parallel and facing each other in an interior 11 (reaction zone) of a reaction chamber 3. A plasma can be excited within the reaction chamber 3 by applying HF power (e.g., 13.56 MHz or 27 MHz) and/or LF power (e.g. 450 kHz) from a power source 25 to one electrode (e.g., electrode 4) and electrically grounding the other electrode (e.g., electrode 2). A temperature regulator may be provided in a lower stage 2 (the lower electrode), and a temperature of a substrate 1 placed thereon may be kept at a desired temperature. The electrode 4 may serve as a gas distribution device, such as a shower plate. Precursor gas, reactant gas, dilution gas, and/or the like may be introduced into reaction chamber 3 using one or more of a gas line 20, a gas line 21, and a gas line 22, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6. In some embodiments, the deposition and treatment steps may be performed in the same reaction space, so that two or more (e.g., all) of the steps can continuously be conducted without exposing the substrate to air or other oxygen-containing atmosphere.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a multiple chamber reactor (two or more sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of depositing a silicon nitride thin film,
the method comprising steps of:
(a) placing a substrate on a susceptor in a reaction chamber;
wherein the substrate comprises a trench;
(b) introducing a silicon precursor into the reaction space;
(c) exposing the substrate to a nitrogen-containing gas to purge excess silicon precursor and byproducts;
(d) introducing the silicon precursor into the reaction space;
(e) exposing the substrate to the nitrogen-containing gas to purge excess silicon precursor and byproducts;
(f) exposing the substrate to reactive species generated by a plasma from the nitrogen-containing gas; and
(g) exposing the substrate to the nitrogen-containing gas to purge excess reactive species and byproducts.

2. The method of claim 1, wherein the nitrogen-containing gas is provided continuously.

3. The method of claim 1, further comprising step (h) introducing a hydrogen-containing gas during step (b).

4. The method of claim 1, further comprising step (i) introducing a hydrogen-containing gas from before step (b) to the end of step (c).

5. The method of claim 4, wherein steps (i), (b) and (c) are repeated N times and steps (d) to (g) are repeated M times.

6. The method of claim 1, wherein the silicon precursor comprises at least one of: HSiI₃, H₂SiI₂, H₃SiI, H₂Si₂I₄, H₄Si₂I₂, H₅Si₂I, H₂SiCl₂, or H₂SiBr₂.

7. The method of claim 1, wherein the method is performed at a temperature between 275° C. and 550° C.

8. The method of claim 1, wherein the method is performed at a pressure between 2 Torr and 22.5 Torr.

9. The method of claim 1, wherein a RF power of the plasma is between 100 W and 2000 W.

10. The method of claim 1, wherein the silicon nitride thin film exhibits more than 90% conformality.

11. The method of claim 10, wherein the conformality is the ratio of the thickness of the sidewall at a point 110 nm from the top in the direction of trench depth to the film thickness at the top of the trench, multiplied by 100.

12. The method of claim 1, wherein a duration of the step (b) is between 0.3 and 3 seconds.

13. The method of claim 1, wherein a duration of the step (c) is between 0.1 and about 1.5 seconds.

14. The method of claim 1, wherein a duration of the step (d) is between 0.3 and about 3 seconds.

15. The method of claim 1, wherein a duration of the step (e) is between 0.1 and about 1.5 seconds.

16. The method of claim 1, wherein a duration of the step (f) is between 3 and about 30 seconds.

17. The method of claim 1, wherein a duration of the step (g) is between 0.1 and about 2 seconds.

18. A substrate processing apparatus to perform the steps of claim 1.
